(19) United States
(12) Patent Application Publication
(10) Pub. No.: US 2026/0086541 A1
(43) Pub. Date: Mar. 26, 2026

(54) SUBSTRATE PROCESSING APPARATUS AND METHOD

(71) Applicant: Manz Taiwan Ltd., Taoyuan City (TW)

(72) Inventors: Cheng-Che WU, Taoyuan City (TW); Hsien-Yi HSIEH, Taoyuan City (TW); Nan-Hao LIN, Taoyuan City (TW)

(21) Appl. No.: 19/010,559

(22) Filed: Jan. 6, 2025

(30) Foreign Application Priority Data
Sep. 20, 2024 (TW) 113135785
Sep. 20, 2024 (TW) 113135787

(51) Int. Cl. G05B 19/418

(52) U.S. Cl. CPC G05B 19/41865; G05B 19/4183; G05B 19/41875; G05B 19/41885; G05B 2219/45212; G05B 2219/49004

(57) ABSTRACT

A substrate processing apparatus and method are configured to inspect an initial substrate after a specific process, either when needed or for the first time. After the initial substrate passes the inspecting process, the device and method can perform the specific process on a subsequent substrate with an accumulated processing time corresponding to the time that the initial substrate spent in the inspecting process. The specific process may include a modification process, an etching process, a hole-filling process, or a coating process. By implementing this approach, the substrate processing apparatus and method can reduce manufacturing and inspection times, thereby improving overall manufacturing yield.

### BACKGROUND OF THE INVENTION

### (a) Field of the Invention

The present disclosure relates to a substrate processing apparatus and method (substrate processing equipment and method), and more particularly, relates to the substrate processing apparatus and method which may inspect an initial substrate after a specific process either when needed or for the first time. After the initial substrate passes the inspecting process, the equipment and method may perform the specific process on a subsequent substrate with an accumulated processing time corresponding to the time that the initial substrate spent in the inspecting process.

### (b) Description of the Prior Art

The substrate processing apparatus may perform specific processes on substrates. Each one of the substrates, after being performed by the specific processes, may be transmitted to an inspection device of an inspection station for inspecting whether each one of the substrates meets a predetermined demand parameter or not. For example, an etching processing equipment may etch glass or silicon substrates to generate through-glass vias (TGV) or through-silicon vias (TSV). Usually, the inspection device of the inspection station may inspect all perforations of the substrates to determine whether each one of the substrates meets the predetermined diameter range (such as the diameter of the upper hole, the diameter of the lower hole, the aspect ratio of the upper hole diameter to the waist diameter).

However, this approach takes a lot of time to perform the inspecting processes. The specific processes are required to be performed again on most of the TGV or TSV substrates while failing the inspecting processes. Or all of the TGV or TSV substrates are regarded as flawed products, such that manufacturing time is increased and manufacturing yield is reduced. Because of this situation, the industry still needs a substrate processing apparatus and method that may reduce the manufacturing and inspection times and may improve the manufacturing yield.

### SUMMARY OF THE INVENTION

One aspect of the present disclosure is a substrate processing apparatus, which may inspect an initial substrate after a specific process either when needed or for the first time, and after the initial substrate passes the inspecting process, the equipment may perform the specific process on a subsequent substrate with an accumulated processing time corresponding to the time that the initial substrate spent in the inspecting process.

According to an embodiment of the present disclosure, a substrate processing apparatus includes a computing unit, a substrate processing device, and an inspecting device. The computing unit is configured to obtain a processing rate and a demand parameter of a specific process. A processing time is computed based on the demand parameter and the processing rate, and an accumulated processing time is initialized. The substrate processing device is electrically connected to the computing unit and is configured to perform the specific process on a substrate with the processing time. The inspecting device is electrically connected to the computing unit and is configured to inspect a through via of the substrate after the specific process such that an inspection result data is generated to the computing unit. When the computing unit determines that the substrate meets the demand parameter based on the inspection result data, the accumulated processing time is recorded by the computing unit. A subsequent substrate is required to meet the demand parameter subsequently, and the substrate processing device is controlled by the computing unit to perform the specific process on the subsequent substrate with the accumulated processing time. When the computing unit determines that the substrate does not meet the demand parameter based on the inspection result data and the substrate may have a chance to meet the demand parameter by performing the specific process again, the processing rate is updated by the computing unit based on the inspection result data and the accumulated processing time, and the processing time and the accumulated processing time are updated based on a demand difference and the processing rate after updated, and the specific process is performed on the substrate with the processing time after updated by the substrate processing device.

In one embodiment of the present disclosure, the substrate processing apparatus further includes a subsequent processing device. The subsequent processing device is electrically connected to the computing unit. When the computing unit determines that the substrate meets the demand parameter based on the inspection result data, the subsequent processing device performs a subsequent process on the substrate.

In one embodiment of the present disclosure, the computing unit controls the substrate processing device to perform the specific process on the subsequent substrate with the accumulated processing time, and the computing unit controls the inspecting device to not inspect the subsequent substrate.

In one embodiment of the present disclosure, when the computing unit determines that the substrate does not meet the demand parameter based on the inspection result data and the substrate cannot meet the demand parameter even by performing the specific process again, the computing unit determines that the substrate is a flawed product.

In one embodiment of the present disclosure, a predetermined processing time is received by the computing unit, the substrate processing device is controlled to perform the specific process on the substrate with the predetermined processing time, the inspecting device is controlled to inspect the substrate to obtain an initial inspection result data, and the processing rate of the specific process is computed by the computing unit based on the initial inspection result data and the predetermined processing time.

In one embodiment of the present disclosure, the demand difference is computed by the computing unit based on the inspection result data and the demand parameter, the computing unit is configured to use a lookup table or a model established by artificial intelligence, regression calculation, or the Monte-Carlo method to compute the processing time based on the demand parameter and the processing rate, and the lookup table or the model is configured to update the processing time based on the demand difference and the processing rate after updated.

In one embodiment of the present disclosure, the specific process is an etching process, the process rate is an etching rate, the demand parameter is a perforation demand parameter, the processing time is an etching time, and the accumulated processing time is an accumulated etching time.

In one embodiment of the present disclosure, the substrate is a glass substrate or a silicon substrate, the through via is a through-glass via (TGV) or a through-silicon via (TSV), and the etching process is an immersion etching process, a wet etching process or a laser etching process.

In one embodiment of the present disclosure, the substrate is a glass substrate, the etching process is an immersion etching process, and before performing the etching process, the glass substrate is performed by a laser modification process to form a plurality of modification areas, etching solution information and laser modification processing information are received by the computing unit, the etching rate of the etching process is determined based on the etching solution information and the laser modification processing information, and the laser modification processing information includes laser power, irradiation time and the number of irradiations for performing the laser modification process.

In one embodiment of the present disclosure, the etching solution used for the etching process performed initially is the same as the etching solution used for the etching process performed subsequently, and after the etching process performed initially and before the etching process performed subsequently, the substrate is not performed by the laser modification process again, and the etching rate is updated by the computing unit based on the inspection result data and the accumulated etching time.

In one embodiment of the present disclosure, the etching solution used for the etching process performed initially is the same as the etching solution used for the etching process performed subsequently, and after the etching process performed initially and before the etching process performed subsequently, the substrate is performed by the laser modification process again, and the etching rate is updated by the computing unit based on the inspection result data, the laser modification processing information and the accumulated etching time.

In one embodiment of the present disclosure, the etching solution used for the etching process performed initially is not the same as the etching solution used for the etching process performed subsequently, and after the etching process performed initially and before the etching process performed subsequently, the substrate is not performed by the laser modification process again, and the etching rate is updated by the computing unit based on the inspection result data, the accumulated etching time and the etching solution information of the etching solution used by the etching process performed subsequently.

In one embodiment of the present disclosure, the etching solution used for the etching process performed initially is not the same as the etching solution used for the etching process performed subsequently, and after the etching process performed initially and before the etching process performed subsequently, the substrate is performed by the laser modification process again, and the etching rate is updated by the computing unit based on the inspection result data, the laser modification processing information, the accumulated etching time and the etching solution information of the etching solution used by the etching process performed subsequently.

Another aspect of the present disclosure is a substrate processing method, which may inspect an initial substrate after a specific process either when needed or for the first time, and after the initial substrate passes the inspecting process, the method may perform the specific process on a subsequent substrate with an accumulated processing time corresponding to the time that the initial substrate spent in the inspecting process.

According to an embodiment of the present disclosure, a substrate processing method is performed in a substrate processing apparatus and includes: obtaining a processing rate and a demand parameter of a specific process; computing a processing time based on the demand parameter and the processing rate, wherein an accumulated processing time is initialized; performing the specific process on a substrate with the processing time; inspecting a through via of the substrate after the specific process to generate an inspection result data to the computing unit; performing a subsequent process to the substrate when the inspection result data determines that the substrate meets the demand parameter, wherein the accumulated processing time is recorded, and a subsequent substrate is required to meet the demand parameter subsequently, the substrate processing apparatus is controlled to perform the specific process on the subsequent substrate with the accumulated processing time; and updating the processing rate based on the inspection result data and the accumulated processing time when the inspection result data determines that the substrate does not meet the demand parameter and the substrate may have a chance to meet the demand parameter by performing the specific process again, wherein the processing time and the accumulated processing time are updated based on a demand difference and the processing rate after updated, and the substrate is performed the specific process with the processing time after updated by the substrate processing apparatus.

In one embodiment of the present disclosure, the substrate processing apparatus is controlled to perform the specific process on the subsequent substrate with the accumulated processing time and is controlled to not inspect the subsequent substrate.

In one embodiment of the present disclosure, when the inspection result data determines that the substrate does not meet the demand parameter and the substrate cannot meet the demand parameter even by performing the specific process again, the substrate is determined to be a flawed product.

In one embodiment of the present disclosure, a predetermined processing time is received, the specific process is performed on the substrate with the predetermined processing time, the substrate is inspected to obtain an initial inspection result data, and the processing rate of the specific process is computed based on the initial inspection result data and the predetermined processing time.

In one embodiment of the present disclosure, the substrate processing method further includes: computing the demand difference based on the inspection result data and the demand parameter; and using a lookup table or a model established by artificial intelligence, regression calculation, or the Monte-Carlo method to compute the processing time based on the demand parameter and the processing rate, wherein the lookup table or the model is configured to update the processing time based on the demand difference and the processing rate after updated.

In one embodiment of the present disclosure, the specific process is a modification process, an etching process, a hole-filling process, or a coating process, and the subsequent process includes at least one of a cleaning process, a drying process, a heating process, a cooling process, and a receiving process.

In one embodiment of the present disclosure, the specific process is an etching process, the process rate is an etching rate, the demand parameter is a perforation demand parameter, the processing time is an etching time, the accumulated processing time is an accumulated etching time, the substrate is a glass substrate or a silicon substrate, the through via is a through-glass via (TGV) or a through-silicon via (TSV), and the etching process is an immersion etching process, a wet etching process or a laser etching process.

In the embodiments of the present disclosure, the substrate processing apparatus and method can reduce manufacturing and inspection times, thereby improving overall manufacturing yield.

To enable a further understanding of said objectives, structures, characteristics, and effects, as well as the technology and methods used in the present invention and effects achieved, a brief description of the drawings is provided below followed by a detailed description of the preferred embodiments.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of a substrate processing apparatus performing a modification process on a substrate according to one embodiment of the present disclosure.

FIG. 2 illustrates a schematic view of a substrate processing apparatus performing a hole-filling process on a substrate according to one embodiment of the present disclosure.

FIG. 3 illustrates a block view of a substrate processing apparatus according to one embodiment of the present disclosure.

FIG. 4 illustrates a flow chart of a substrate processing method according to one embodiment of the present disclosure.

### DETAILED DESCRIPTION OF THE PREFERRED EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” “front,” “back” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

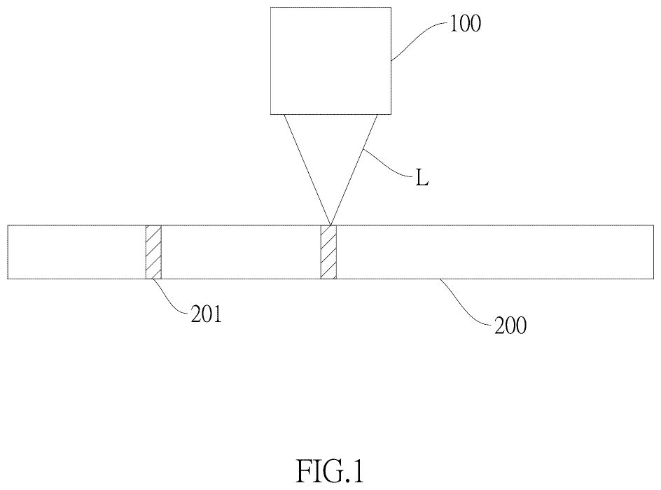

Please refer to FIG. 1, FIG. 1 illustrates a schematic view of a substrate processing apparatus performing a modification process on a substrate according to one embodiment of the present disclosure. In one embodiment, the substrate processing apparatus of the present disclosure may be a substrate modification processing equipment that performs modification processing. The substrate modification processing equipment includes a laser light source 100. The laser light source 100 is used to emit a laser beam L to illuminate a modified area 201 of a substrate 200 (such as a glass substrate or a silicon substrate). The modified area 201 will be modified after being irradiated with the laser beam L for a processing time. Generally, the modification area 201 is needed to meet predetermined requirements. For example, a spectrum of the modified region 201 (the spectrum may be inspected by a X-ray spectrometer) must meet at least one of the demand parameters. For example, whether the measured spectrum is similar to the expected spectrum.

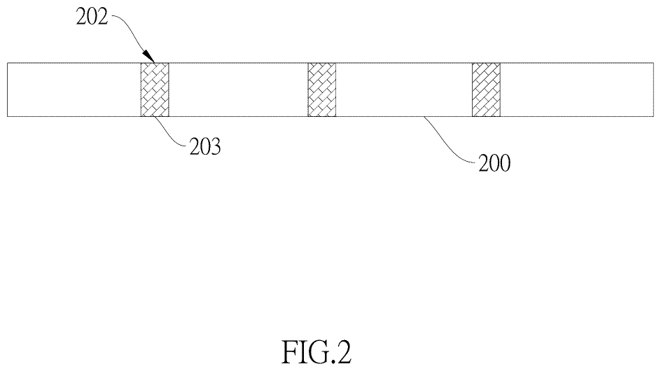

Please refer to FIG. 2, FIG. 2 illustrates a schematic view of a substrate processing apparatus performing a hole-filling process on a substrate according to one embodiment of the present disclosure. In another embodiment, the substrate processing apparatus of the present disclosure may be a through-via substrate etching equipment. After the substrate 200 shown in FIG. 1 is modified and meets at least one of the demand parameters, the through-via substrate etching equipment etches the substrate 200 shown in FIG. 1 to form a through via 202 in the modified area 201 as shown in FIG. 2. The substrate 200 becomes a through-via substrate. Furthermore, the through-via substrate etching equipment may be an etching solution immersion tank equipment which is used to immerse the modified substrate 200 in the etching solution. After a period of the processing time, the substrate 200 is removed from the etching solution to form the through via 202 in the modified area 201 as shown in FIG. 2. The through via 202 must meet at least one of the demand parameters. The demand parameter is a perforation demand parameter, such as the diameter of the upper hole, the diameter of the lower hole, the aspect ratio of the upper hole diameter to the waist diameter, or the roughness of the inner surface of the via.

In another embodiment, the substrate processing apparatus of the present disclosure may be a substrate coating equipment. The substrate coating equipment is one type of the substrate hole-filling equipment. But the substrate coating equipment is not limited to the hole-filling applications. The substrate hole-filling equipment may fill holes in a non-coating manner. The substrate coating equipment is used to coat a metal into the through via 202 with the processing time to form a metal conductive pillar 203. The metal coating degree of the through via 202 must meet at least one of the demand parameters, such as the hole-filling density. Then, the substrate 200 after the specific process can be used as an intermediary substrate when packaging 3-dimensional wafers or 2.5-dimensional wafers.

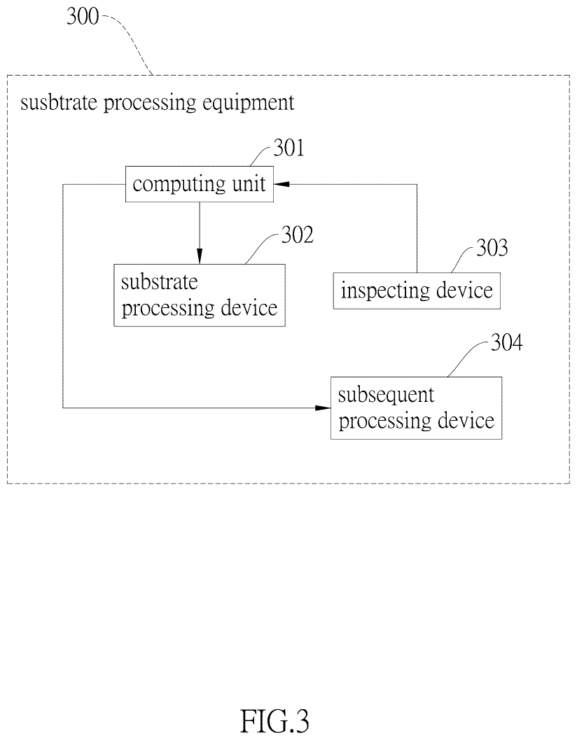

Please refer to FIG. 3, FIG. 3 illustrates a block view of a substrate processing apparatus according to one embodiment of the present disclosure. The substrate processing apparatus 300 includes a computing unit 301, a substrate processing device 302, and an inspecting device 303. The computing unit 301 is configured to obtain an initial processing rate and at least one expected demand parameter of a specific process. A processing time is computed based on the expected demand parameter and the processing rate, and an accumulated processing time is initialized. The substrate processing device 302 is electrically connected to the computing unit 301 and is configured to perform the specific process on a substrate with the processing time. The inspecting device 303 is electrically connected to the computing unit 301 and is configured to inspect a through via of the substrate after the specific process such that an inspection result data is generated to the computing unit 301. The inspecting device 303 may be automatic optical inspecting equipment. The automatic optical inspecting equipment can inspect at least one of spectrum, image, light transmittance, refractive index and reflectance, and the present disclosure is not limited in this regard.

Furthermore, a predetermined processing time is received by the computing unit 301. The substrate processing device 302 is controlled to perform the specific process on the substrate with the predetermined processing time. The inspecting device 303 is controlled to inspect the substrate to obtain an initial inspection result data, and the initial processing rate of the specific process is computed by the computing unit 301 based on the initial inspection result data and the predetermined processing time.

When the computing unit 301 determines that the substrate meets the expected demand parameter based on the inspection result data, the accumulated processing time is recorded by the computing unit 301. A subsequent substrate is required to meet the demand parameter subsequently, and the substrate processing device 302 is controlled by the computing unit 301 to perform the specific process on the subsequent substrate with the accumulated processing time. In addition, the computing unit 301 controls the substrate processing device 302 to perform the specific process on the subsequent substrate with the accumulated processing time, and the computing unit 301 controls the inspecting device 303 to not inspect the subsequent substrate.

When the computing unit 301 determines that the substrate does not meet the expected demand parameter based on the inspection result data and the substrate may have a chance to meet the expected demand parameter by performing the specific process again, the processing rate is updated by the computing unit 301 based on the inspection result data and the accumulated processing time. The processing time and the accumulated processing time are updated based on a demand difference and the processing rate after updated. The specific process is performed on the substrate with the processing time after updated by the substrate processing device 302.

Furthermore, the demand difference is computed by the computing unit 301 based on the inspection result data and the expected demand parameter. The computing unit 301 is configured to use a lookup table or a model to compute the initial processing time based on the demand parameter and the initial processing rate. The model is established by artificial intelligence, regression calculation, or the Monte-Carlo method. The lookup table or the model is configured to update the processing time based on the demand difference and the processing rate after updated.

Furthermore, when the computing unit 301 determines that the substrate does not meet the expected demand parameter based on the inspection result data and the substrate cannot meet the expected demand parameter even by performing the specific process again, the computing unit 301 determines that the substrate is a flawed product.

Simply, the substrate processing apparatus 300 is configured to inspect an initial substrate after a specific process, either when needed or for the first time. After the initial substrate passes the inspecting process, the substrate processing apparatus 300 can perform the specific process on a subsequent substrate with an accumulated processing time corresponding to the time that the initial substrate spent in the inspecting process.

In this way, a plurality of the substrates after the specific process do not need to be inspected, so the inspection time and manufacturing time can be reduced. In addition, other subsequent substrates are performed the specific process with the accumulated processing time corresponding to the inspection. Therefore, unless the substrate processing apparatus 300 has serious deviation or aging due to the environment, most of the subsequent substrates after the specific process will meet the demand parameter. The substrate processing apparatus 300 can also effectively improve the manufacturing yield. The substrate processing apparatus 300 may inspect an initial substrate after a specific process either when needed or for the first time. After the initial substrate passes the inspecting process, the substrate processing apparatus 300 may perform the specific process on a subsequent substrate with an accumulated processing time corresponding to the time that the initial substrate spent in the inspecting process. The specific process may be a modification process, an etching process, a hole-filling process or a coating process.

In addition, the substrate processing apparatus 300 further includes a subsequent processing device 304. The subsequent processing device 304 is electrically connected to the computing unit 301. When the computing unit 301 determines that the substrate meets the expected demand parameter based on the inspection result data, the subsequent processing device 304 performs a subsequent process on the substrate.

Moreover, the specific process is a modification process, an etching process, a hole-filling process, or a coating process. The substrate processing apparatus 300 may be a substrate modification processing equipment, a perforated substrate etching processing equipment, a blind-via substrate etching processing equipment, a substrate etching processing equipment, a substrate hole-filling processing equipment, or a substrate coating processing equipment. In addition, the subsequent process includes at least one of a cleaning process, a drying process, a heating process, a cooling process, and a receiving process. The specific process and the subsequent process are not limited in this regard. The specific process is an etching process, the process rate is an etching rate, the demand parameter is a perforation demand parameter, the processing time is an etching time, and the accumulated processing time is an accumulated etching time. The substrate is a glass substrate or a silicon substrate, the through via is a through-glass via (TGV) or a through-silicon via (TSV), and the etching process is an immersion etching process, a wet etching process or a laser etching process.

When the substrate processing apparatus 300 is the perforated substrate etching processing equipment, the process rate is an etching rate, the predetermined processing time is a predetermined etching time, the processing time is an etching time, the accumulated processing time is an accumulated etching time, and the demand parameter is a perforation demand parameter. In addition, the substrate is a glass substrate or a silicon substrate, the through via on the substrate is a through-glass via (TGV) or a through-silicon via (TSV). The etching process is an immersion etching process, a wet etching process or a laser etching process. The inspecting device 303 is used to inspect at least one through via of the substrate.

The substrate is a glass substrate and the etching process is an immersion etching process. Before performing the etching process, the glass substrate is performed by a laser modification process to form a plurality of modification areas. The etching solution information and the laser modification processing information are received by the computing unit 301. The initial etching rate of the etching process is determined based on the etching solution information and the laser modification processing information. The laser modification processing information includes laser power, irradiation time and the number of irradiations for performing the laser modification process. The accumulated etching time is the sum of the initial etching time and the preset etching time. If the substrate is etched with the initial etching time and the through via formed in the modified area is able to meet the perforation demand parameters (for example, the diameter of the upper hole of the perforation demand parameter is 50 microns), the other modified substrates are etched with the recorded accumulated etching time.

The accumulated etching time is the initial etching time. If the substrate is etched with the initial etching time and the through via formed in the modified zone does not meet the perforation demand parameter (for example, the diameter of the upper hole of the perforation demand parameter is 50 microns, and the diameter of the upper hole at this time is 40 microns, which means the demand parameter may be meted by performing the etching process again), the updated etching time is computed based on the demand difference (such as 10 microns) and the updated etching rate. The accumulated etching time at this time is the sum of the preset etching time, the initial etching time and the updated etching time. After the etching process is performed again, if the substrate can meet the perforation demand parameter, other modified substrates will be etched with the recorded accumulated etching time.

In this embodiment, it is noted that the laser modification process before the etching process may illuminate the substrate with a single laser. The laser modification process may also illuminate the substrate multiple times with multiple different lasers. Or the laser modification process may illuminate the substrate multiple times with a single laser. Therefore, the laser modification processing information will affect the etching rate. The etching solution used for the etching process performed initially is the same as the etching solution used for the etching process performed subsequently. After the etching process performed initially and before the etching process performed subsequently, the substrate is not performed by the laser modification process again. The etching rate is updated by the computing unit 301 based on the inspection result data (such as the diameter of the upper hole) and the accumulated etching time.

In this embodiment, it is noted that the etching solution used for the etching process performed initially is the same as the etching solution used for the etching process performed subsequently, and after the etching process performed initially and before the etching process performed subsequently, the substrate is performed by the laser modification process again. The etching rate is updated by the computing unit 301 based on the inspection result data (such as the diameter of the upper hole), the laser modification processing information and the accumulated etching time.

In this embodiment, it is noted that the etching solution used for the etching process performed initially is not the same as the etching solution used for the etching process performed subsequently. After the etching process performed initially and before the etching process performed subsequently, the substrate is not performed by the laser modification process again. The etching rate is updated by the computing unit 301 based on the inspection result data (such as the diameter of the upper hole), the accumulated etching time and the etching solution information of the etching solution used by the etching process performed subsequently.

In this embodiment, it is noted that the etching solution used for the etching process performed initially is not the same as the etching solution used for the etching process performed subsequently. After the etching process performed initially and before the etching process performed subsequently, the substrate is performed by the laser modification process again. The etching rate is updated by the computing unit 301 based on the inspection result data (such as the diameter of the upper hole), the laser modification processing information, the accumulated etching time and the etching solution information of the etching solution used by the etching process performed subsequently.

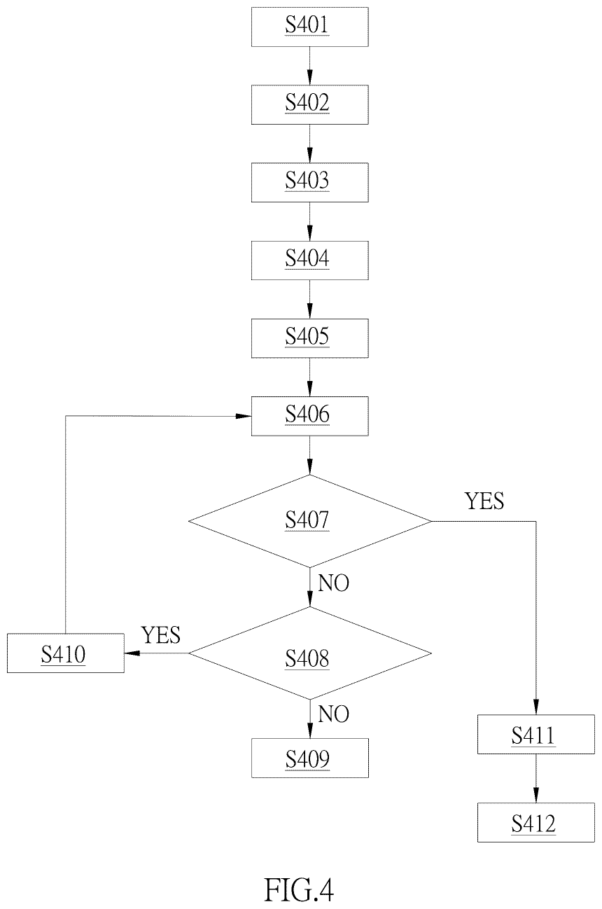

Please refer to FIG. 4, FIG. 4 illustrates a flow chart of a substrate processing method according to one embodiment of the present disclosure. a substrate processing method is performed in the substrate processing apparatus 300 aforementioned. The substrate processing method includes step S401 to step S412. First of all, a demand parameter is received by a computing unit. In step S402, a predetermined processing time is received by the computing unit. The predetermined processing time may be determined by the computing unit or an input, and it is not limited in this regard. In step S403, a substrate processing device is controlled by the computing unit to perform a specific process on a substrate with the predetermined processing time. The specific process may be a modification process, an etching process, a hole-filling process or a coating process, and it is not limited in this regard. In step S404, an inspecting device is controlled by the computing unit to inspect the substrate to generate an initial inspection result data, and the initial processing rate of the specific process is computed by the computing unit based on the initial inspection result date and the predetermined processing time. Step S402 to step S404 may be omitted, and the computing unit has the initial processing rate of the specific process at first.

In step S405, the initial processing time is computed by the computing unit based on the demand parameter and the initial processing rate, and an accumulated processing time is initialized. The initial accumulated processing time is the sum of the initial processing time and the predetermined processing time. In addition, step S402 to step S404 may be omitted, and the initial accumulated processing time is the initial processing time. In step S406, the substrate processing device is controlled by the computing unit to perform the specific process on the substrate with the processing time.

In step 407, a through via of the substrate after the specific process is inspected to generate an inspection result data to the computing unit. The computing unit determines the substrate meets the expected demand parameter based on the inspection result data. If the substrate meets the expected demand parameter based on the inspection result data, step S411 is performed. If the substrate does not meet the expected demand parameter based on the inspection result data, step S408 is performed. In step S411, if the substrate meets the expected demand parameter based on the inspection result data, the accumulated processing time is recorded by the computing unit. in step S412, the substrate processing device is controlled by the computing unit to perform a subsequent process to the substrate when the inspection result data determines that the substrate meets the demand parameter. The subsequent process includes at least one of a cleaning process, a drying process, a heating process, a cooling process, and a receiving process, and it is not limited in this regard. In this way, the substrate processing apparatus can perform the specific process on other subsequent substrates that subsequently need to meet the demand parameter with a recorded accumulated processing time, and the substrate processing apparatus can selectively no longer inspect other subsequent substrates that have been performed by the specific process.

In step S408, if the substrate does not meet the expected demand parameter, the computing unit may determine whether the substrate can meet the expected demand parameter or not by performing the specific process again based on the inspection result data. When the inspection result data determines that the substrate can meet the expected demand parameter by performing the specific process again, step S410 is performed. If the inspection result data determines that the substrate cannot meet the expected demand parameter even by performing the specific process again, step S409 is performed. In step S409, if the inspection result data determines that the substrate cannot meet the expected demand parameter even by performing the specific process again, the computing unit determines that the substrate is a flawed product. The substrate regarded as the flawed product may be collected in a flawed area.

In step S410, if the inspection result data determines that the substrate can meet the expected demand parameter by performing the specific process again, the processing rate is updated by the computing unit based on the inspection result data and the accumulated processing time. The processing time and the accumulated processing time are updated based on a demand difference and the processing rate after updated. The demand difference is computed by the computing unit based on the inspection result data and the expected demand parameter. In step S406, the substrate processing apparatus is controlled by the computing unit to perform the specific process on the substrate with the processing time after updated.

It is noted that a lookup table or a model established by artificial intelligence, regression calculation, or the Monte-Carlo method is used to compute the processing time based on the demand parameter and the processing rate. The lookup table or the model is configured to update the processing time based on the demand difference and the processing rate after updated.

It is noted that the specific process is an etching process, the process rate is an etching rate, the demand parameter is a perforation demand parameter, the processing time is an etching time, and the accumulated processing time is an accumulated etching time. The substrate is a glass substrate or a silicon substrate, the through via is a through-glass via (TGV) or a through-silicon via (TSV), and the etching process is an immersion etching process, a wet etching process or a laser etching process. The substrate is a glass substrate, the etching process is an immersion etching process. Before performing the etching process, the glass substrate is performed by a laser modification process to form a plurality of modification areas. The etching solution information and the laser modification processing information are received by the computing unit. The etching rate of the etching process is determined based on the etching solution information and the laser modification processing information. The laser modification processing information includes laser power, irradiation time and the number of irradiations for performing the laser modification process.

In summary, the present disclosure presents the substrate processing apparatus and method, which may inspect an initial substrate after a specific process either when needed or for the first time. After the initial substrate passes the inspecting process, the substrate processing apparatus and method may perform the specific process on a subsequent substrate with an accumulated processing time corresponding to the time that the initial substrate spent in the inspecting process. The specific process may be a modification process, an etching process, a hole-filling process or a coating process. By implementing this approach, the substrate processing apparatus and method can reduce manufacturing and inspection times, thereby improving overall manufacturing yield.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions to not depart from the spirit and scope of the present disclosure, and that they may make various changes, substitutions, and alterations herein without departing from the spirit and scope of the present disclosure.

It is of course to be understood that the embodiments described herein are merely illustrative of the principles of the invention and that a wide variety of modifications thereto may be effected by persons skilled in the art without departing from the spirit and scope of the invention as set forth in the following claims.

1. A substrate processing apparatus, comprising:
a computing unit, configured to obtain a processing rate and a demand parameter of a specific process, wherein a processing time is computed based on the demand parameter and the processing rate, and an accumulated processing time is initialized;
a substrate processing device, electrically connected to the computing unit and configured to perform the specific process on a substrate with the processing time; and
an inspecting device, electrically connected to the computing unit and configured to inspect a through via of the substrate after the specific process such that an inspection result data is generated to the computing unit;
wherein when the computing unit determines that the substrate meets the demand parameter based on the inspection result data, the accumulated processing time is recorded by the computing unit, wherein a subsequent substrate is required to meet the demand parameter subsequently, the substrate processing device is controlled by the computing unit to perform the specific process on the subsequent substrate with the accumulated processing time; wherein when the computing unit determines that the substrate does not meet the demand parameter based on the inspection result data and the substrate may have a chance to meet the demand parameter by performing the specific process again, the processing rate is updated by the computing unit based on the inspection result data and the accumulated processing time, and the processing time and the accumulated processing time are updated based on a demand difference and the processing rate after updated, and the specific process is performed on the substrate with the processing time after updated by the substrate processing device.

2. The substrate processing apparatus of claim 1, further comprising:
a subsequent processing device, electrically connected to the computing unit, wherein when the computing unit determines that the substrate meets the demand parameter based on the inspection result data, the subsequent processing device performs a subsequent process on the substrate.

3. The substrate processing apparatus of claim 1, wherein the computing unit controls the substrate processing device to perform the specific process on the subsequent substrate with the accumulated processing time, and the computing unit controls the inspecting device to not inspect the subsequent substrate.

4. The substrate processing apparatus of claim 1, wherein when the computing unit determines that the substrate does not meet the demand parameter based on the inspection result data and the substrate cannot meet the demand parameter even by performing the specific process again, the computing unit determines that the substrate is a flawed product.

5. The substrate processing apparatus of claim 1, wherein a predetermined processing time is received by the computing unit, the substrate processing device is controlled to perform the specific process on the substrate with the predetermined processing time, the inspecting device is controlled to inspect the substrate to obtain an initial inspection result data, and the processing rate of the specific process is computed by the computing unit based on the initial inspection result data and the predetermined processing time.

6. The substrate processing apparatus of claim 1, wherein the demand difference is computed by the computing unit based on the inspection result data and the demand parameter, the computing unit is configured to use a lookup table or a model established by artificial intelligence, regression calculation, or the Monte-Carlo method to compute the processing time based on the demand parameter and the processing rate, and the lookup table or the model is configured to update the processing time based on the demand difference and the processing rate after updated.

7. The substrate processing apparatus of claim 1, wherein the specific process is an etching process, the process rate is an etching rate, the demand parameter is a perforation demand parameter, the processing time is an etching time, and the accumulated processing time is an accumulated etching time.

8. The substrate processing apparatus of claim 7, wherein the substrate is a glass substrate or a silicon substrate, the through via is a through-glass via (TGV) or a through-silicon via (TSV), and the etching process is an immersion etching process, a wet etching process or a laser etching process.

9. The substrate processing apparatus of claim 7, wherein the substrate is a glass substrate, the etching process is an immersion etching process, and before performing the etching process, the glass substrate is performed by a laser modification process to form a plurality of modification areas, etching solution information and laser modification processing information are received by the computing unit, the etching rate of the etching process is determined based on the etching solution information and the laser modification processing information, and the laser modification processing information includes laser power, irradiation time and the number of irradiations for performing the laser modification process.

10. The substrate processing apparatus of claim 9, wherein the etching solution used for the etching process performed initially is the same as the etching solution used for the etching process performed subsequently, and after the etching process performed initially and before the etching process performed subsequently, the substrate is not performed by the laser modification process again, and the etching rate is updated by the computing unit based on the inspection result data and the accumulated etching time.

11. The substrate processing apparatus of claim 9, wherein the etching solution used for the etching process performed initially is the same as the etching solution used for the etching process performed subsequently, and after the etching process performed initially and before the etching process performed subsequently, the substrate is performed by the laser modification process again, and the etching rate is updated by the computing unit based on the inspection result data, the laser modification processing information and the accumulated etching time.

12. The substrate processing apparatus of claim 9, wherein the etching solution used for the etching process performed initially is not the same as the etching solution used for the etching process performed subsequently, and after the etching process performed initially and before the etching process performed subsequently, the substrate is not performed by the laser modification process again, and the etching rate is updated by the computing unit based on the inspection result data, the accumulated etching time and the etching solution information of the etching solution used by the etching process performed subsequently.

13. The substrate processing apparatus of claim 9, wherein the etching solution used for the etching process performed initially is not the same as the etching solution used for the etching process performed subsequently, and after the etching process performed initially and before the etching process performed subsequently, the substrate is performed by the laser modification process again, and the etching rate is updated by the computing unit based on the inspection result data, the laser modification processing information, the accumulated etching time and the etching solution information of the etching solution used by the etching process performed subsequently.

14. A substrate processing method performed in a substrate processing apparatus, the substrate processing method comprising:
obtaining a processing rate and a demand parameter of a specific process;
computing a processing time based on the demand parameter and the processing rate, wherein an accumulated processing time is initialized;
performing the specific process on a substrate with the processing time;
inspecting a through via of the substrate after the specific process to generate an inspection result data to the computing unit;
performing a subsequent process to the substrate when the inspection result data determines that the substrate meets the demand parameter, wherein the accumulated processing time is recorded, and a subsequent substrate is required to meet the demand parameter subsequently, the substrate processing apparatus is controlled to perform the specific process on the subsequent substrate with the accumulated processing time; and
updating the processing rate based on the inspection result data and the accumulated processing time when the inspection result data determines that the substrate does not meet the demand parameter and the substrate may have a chance to meet the demand parameter by performing the specific process again, wherein the processing time and the accumulated processing time are updated based on a demand difference and the processing rate after updated, and the substrate is performed the specific process with the processing time after updated by the substrate processing apparatus.

15. The substrate processing method of claim 14, wherein the substrate processing apparatus is controlled to perform the specific process on the subsequent substrate with the accumulated processing time and is controlled to not inspect the subsequent substrate.

16. The substrate processing method of claim 14, wherein when the inspection result data determines that the substrate does not meet the demand parameter and the substrate cannot meet the demand parameter even by performing the specific process again, the substrate is determined to be a flawed product.

17. The substrate processing method of claim 14, wherein a predetermined processing time is received, the specific process is performed on the substrate with the predetermined processing time, the substrate is inspected to obtain an initial inspection result data, and the processing rate of the specific process is computed based on the initial inspection result data and the predetermined processing time.

18. The substrate processing method of claim 14, further comprising:
computing the demand difference based on the inspection result data and the demand parameter; and
using a lookup table or a model established by artificial intelligence, regression calculation, or the Monte-Carlo method to compute the processing time based on the demand parameter and the processing rate, wherein the lookup table or the model is configured to update the processing time based on the demand difference and the processing rate after updated.

19. The substrate processing method of claim 14, wherein the specific process is a modification process, an etching process, a hole-filling process, or a coating process, and the subsequent process includes at least one of a cleaning process, a drying process, a heating process, a cooling process, and a receiving process.

20. The substrate processing method of claim 14, wherein the specific process is an etching process, the process rate is an etching rate, the demand parameter is a perforation demand parameter, the processing time is an etching time, the accumulated processing time is an accumulated etching time, the substrate is a glass substrate or a silicon substrate, the through via is a through-glass via (TGV) or a through-silicon via (TSV), and the etching process is an immersion etching process, a wet etching process or a laser etching process.
